(19) United States
(12) Patent Application Publication
(10) Pub. No.: US 2009/0002885 A1
(43) Pub. Date: Jan. 1, 2009

(54) PERPENDICULAR MAGNETIC RECORDING HEAD AND METHOD OF MANUFACTURING THE SAME

(75) Inventor: Kyusik SIN, Seongnam-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 11/945,479

(22) Filed: Nov. 27, 2007

(30) Foreign Application Priority Data
Jun. 28, 2007 (KR) 10-2007-0064603

(51) Int. Cl. G11B 5/147; H01L 21/00

(52) U.S. Cl. 360/125.02; 438/3; 257/E21.001

(57) ABSTRACT

Provided are a perpendicular magnetic recording (PMR) head and a method of manufacturing the same. The PMR head includes a main pole, a return yoke, and a coil to which current is supplied so that the main pole generates a magnetic field required for recording data in a recording medium. The PMR head further includes side shields disposed on both sides of the main pole to be spaced a first gap apart from the main pole; and a top shield disposed opposite the main pole and the side shields to be spaced a second gap apart from the main pole and the side shields at one end of the return yoke.

### CROSS-REFERENCE TO RELATED PATENT APPLICATION

This application claims the benefit of Korean Patent Application No. 10-2007-0064603, filed on Jun. 28, 2007, in the Korean Intellectual Property Office, the disclosure of which is incorporated herein in its entirety by reference.

### BACKGROUND OF THE INVENTION

1. Field of the Invention

The present invention relates to a perpendicular magnetic recording head and a method of manufacturing the same, and more particularly, to a perpendicular magnetic recording head having a return yoke tip divided into a plurality of shields wrapped around a main pole, and a method of manufacturing the same.

2. Description of the Related Art

Magnetic recording heads for hard disk drives are used to record and read data. Rapid industrialization and development of information-oriented society have led to a great increase in the quantity of data used by individuals or groups, so that high-density magnetic recording heads for hard disk drives are being required. Magnetic recording methods may be mainly classified into longitudinal magnetic recording methods and perpendicular magnetic recording methods. The longitudinal magnetic recording method involves magnetizing a magnetic layer in a direction parallel to the surface of the magnetic layer to record data, and the perpendicular magnetic recording method involves recording data magnetizing the magnetic layer in a direction vertical to the surface of the magnetic layer to record data. Since the perpendicular magnetic recording method is superior in terms of the recording density to the longitudinal magnetic recording method, PMR heads having various structures have been developed.

In order to obtain high recording density, a wrap-around-shield perpendicular magnetic recording (PMR) head has been disclosed in IEEE Transactions on Magnetics, Vol. 38, No. 4, July 2002.

FIG. 1A is a cross-sectional view of a conventional PMR head 10 described in the above paper, and FIG. 1B is a magnified perspective view of a wrap-around-shield return yoke tip 62 shown in FIG. 1A.

Referring to FIGS. 1A and 1B, the conventional PMR head 10 includes a recording head W and a read head R. The recording head W includes a main pole 50, a return yoke 60, a sub-yoke 40, and a coil C. The read head R includes two magnetic shield layers 30 and a magneto-resistive (MR) element 20 interposed between the magnetic shield layers 30. The return yoke tip 62 is formed at an end of the return yoke 60 and disposed opposite the main pole 50 with a gap therebetween. The return yoke tip 62 is wrapped around an end tip of the main pole 50. The coil C is wound around the main pole 50 and the sub-yoke 40 in a solenoid shape. When a current is supplied to the coil C, the main pole 50, the sub-yoke 40, and the return yoke 60 form a magnetic path of a magnetic field. The magnetic path that proceeds towards a recording medium (not shown) from the main pole 50 magnetizes a recording layer of the recording medium in a vertical direction and returns to the return yoke tip 62 and thus, recording is performed. Also, The magneto-resistive element 20 can read data recorded in the recording medium by the characteristics of changing electrical resistance by a magnetic signal generated from the magnetization of the recording layer

As is known, the PMR head 10 including the return yoke 60 has a better field gradient characteristic than a single-pole PMR head including only the main pole 50. Also, as illustrated in FIG. 1B, the return yoke tip 62, which is wrapped around the end tip of the main pole 50, is designed such that the field gradient characteristic of the PMR head 10 improves around the corners of a track to reduce a track pitch. However, since the return yoke tip 62 of the PMR head 10 of FIG. 1B has high topography, manufacturing the PMR head 10 is not easy. In particular, a throat height TH significantly affects the design of the return yoke tip 62. If the return yoke tip 62 has a great throat height TH, the magnetic field of the main pole 50 that does not pass through a recording medium but travels directly to the return yoke tip 62 increases, thus reducing recording efficiency. Therefore, it is important to appropriately control the throat height TH. However, when the return yoke tip 62 of the PMR head 10 has high topography, it is difficult to control the throat height TH, so that the variation of the throat height TH increases, thereby impeding mass production.

### SUMMARY OF THE INVENTION

The present invention provides a perpendicular magnetic recording (PMR) head having a return yoke tip divided into a plurality of shields wrapped around a main pole, and a method of manufacturing the same.

According to an aspect of the present invention, there is provided a PMR head comprising a main pole, a return yoke, and a coil to which current is supplied so that the main pole generates a magnetic field required for recording data in a recording medium. The PMR head includes side shields disposed on both sides of the main pole, each side shield being spaced a first gap apart from the main pole; and a top shield disposed over and across a top region of the main pole and top regions of the side shields, the top shield being spaced a second gap apart from the main pole and spaced a predetermined distance part from the side shield.

The distance between the top shield and the side shield may be equal to the second gap.

A throat height of the side shield may be equal to or greater than a throat height of the top shield.

According to another aspect of the present invention, there is provided a method of manufacturing a PMR head. The method includes: forming a main pole and forming side shields on both sides of the main pole to be spaced a first gap apart from the main pole; and forming a top shield over and across a top region of the main pole and top regions of the side shields to be spaced a second gap apart from the main pole and be spaced a predetermined distance apart from the side shield.

In an embodiment of the present invention, the formation of the main pole and the side shields may include: forming the main pole; forming a first insulating layer to enclose top and lateral surfaces of the main pole to a thickness almost equal to the first gap; forming a magnetic layer to form the side shields, wherein the magnetic layer encloses top and lateral surfaces of the first insulating layer; and polishing a portion of the magnetic layer and the first insulating layer which is formed on the main pole.

In another embodiment of the present invention, the formation of the main pole and the side shields may include: sequentially forming a first insulating layer and a stop layer; forming a trench having the same shape as the main pole by etching the first insulating layer and the stop layer; forming a magnetic layer in the trench and on the stop layer; polishing the magnetic layer; etching both lateral portions of the first insulating layer; and forming the side shields on both sides of the first insulating layer.

### BRIEF DESCRIPTION OF THE DRAWINGS

The above and other features and advantages of the present invention will become more apparent by describing in detail exemplary embodiments thereof with reference to the attached drawings in which:

FIG. 1A is a cross-sectional view of a conventional perpendicular magnetic recording (PMR) head;

FIG. 1B is a magnified perspective view of a return yoke tip shown in FIG. 1A;

FIG. 2A is a cross-sectional view of a PMR head according to an embodiment of the present invention;

FIG. 2B is a magnified perspective view of a return yoke tip shown in FIG. 2A;

FIGS. 3A through 3F are diagrams for explaining a method of manufacturing a PMR head according to an embodiment of the present invention; and

FIGS. 4A through 4F are diagrams for explaining a method of manufacturing a PMR head according to another embodiment of the present invention.

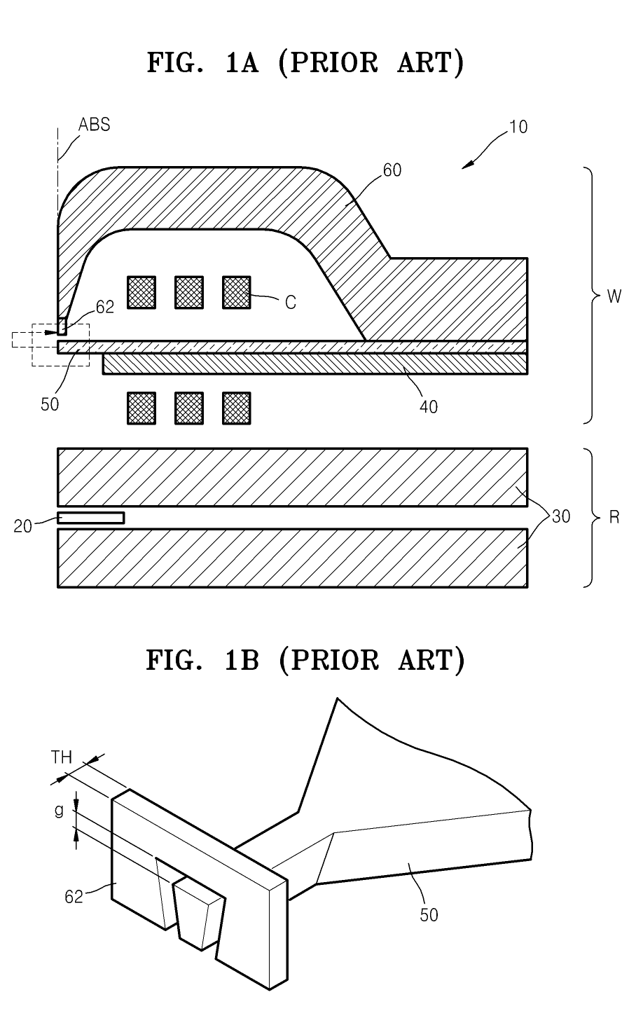

### DETAILED DESCRIPTION OF THE INVENTION

A perpendicular magnetic recording (PMR) head and a method of manufacturing the same according to the present invention will now be described more fully hereinafter with reference to the accompanying drawings, in which exemplary embodiments of the invention are shown. In the drawings, the thicknesses of layers and regions are exaggerated for clarity. The same reference numerals are used to denote the same elements throughout the specification.

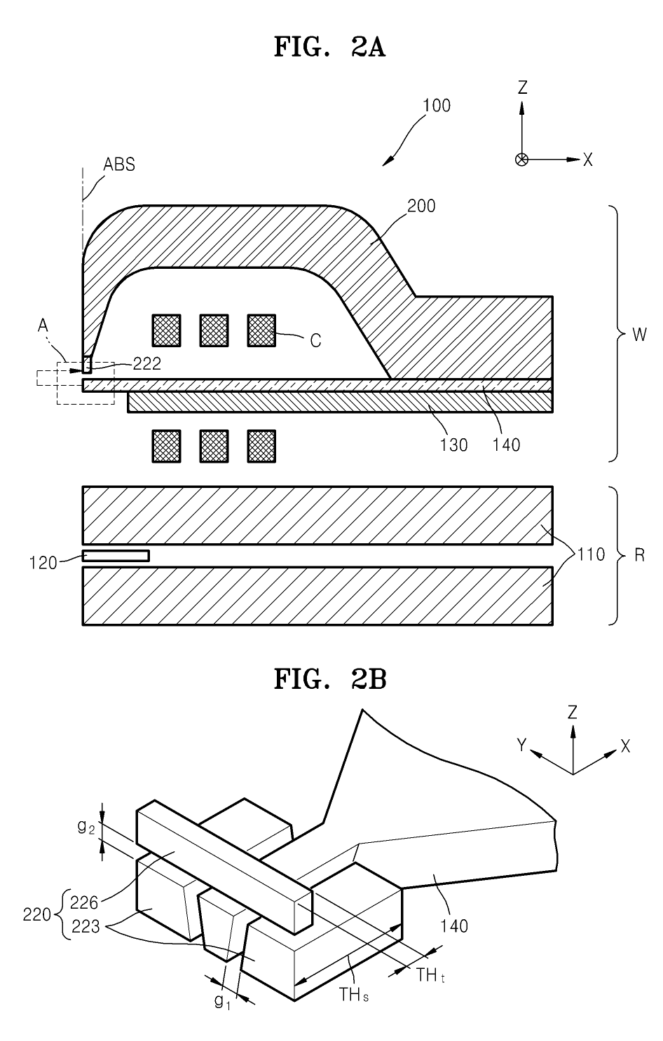

FIG. 2A is a cross-sectional view of a PMR head 100 according to an embodiment of the present invention, and FIG. 2B is a magnified perspective view of a return yoke tip 220 shown in FIG. 2A.

Referring to FIGS. 2A and 2B, the PMR head 100 includes a recording head W to record data in a recording medium (not shown) that is spaced a predetermined distance apart from an air bearing surface (ABS). The recording head W includes a main pole 140, a coil C, a return yoke 200, and a return yoke tip 220. The main pole 140 applies a magnetic field to the recording medium, and a current is supplied to the coil C so that the main pole 140 generates the magnetic field. The return yoke 200 forms a magnetic path along with the main pole 140, and the return yoke tip 220 is disposed at an end of the return yoke 200 and is wrapped around the main pole 140. The PMR head 100 further includes a read head R to read the data recorded in the recording medium. The read head 100 includes two magnetic shield layers 110 and a magneto-resistive (MR) element 120 interposed between the magnetic shield layers 110.

The recording head W may further include a sub-yoke 130, which aids the magnetic field to focus on an end tip of the main pole 140 that is disposed adjacent to the ABS. The sub-yoke 130 is separated away from the end tip of the main pole 140 adjacent to the ABS to aid the magnetic field to focus on the end tip of the main pole 140. Although in FIG. 2A the sub-yoke 130 is illustrated on a bottom surface of the main pole 140, the sub-yoke 130 may be formed on a top surface of the main pole 140. The main pole 140, the return yoke tip 220, the return yoke 200, and the sub-yoke 130 may be formed of a magnetic material so as to form a magnetic path of a recording magnetic field generated by the main pole 140. In this case, since the intensity of the magnetic field focused on the end tip of the main pole 140 is restricted by a saturation magnetic flux density Bs of the main pole 140, the main pole 140 may be formed of a magnetic material having a higher saturation magnetic flux density Bs than the return yoke 200 or the sub-yoke 130. The main pole 140 may be formed of a material having a saturation magnetic flux density Bs of about 2.1 to 2.4 T, for example, CoFe, CoNiFe, and NiFe. The sub-yoke 130 and the return yoke 200 may be formed to have a higher magnetic permeability than the main pole 140 so that the sub-yoke 130 or the return-yoke 200 can have high-speed response to a change in high frequency magnetic field. The sub-yoke 130 and the return yoke 200 may be formed of NiFe, and can have appropriate saturation magnetic flux density Bs and magnetic permeability by controlling a content ratio of Ni to Fe.

The coil C, in the form of a solenoid, is wound around the main pole 140 and the sub-yoke 130 three times. However, the shape or the number of winding turns of the coil C are just examples, and the coil C may have any structure as long as it generates the magnetic field applied to the recording medium on the end tip of the main pole 140 adjacent to the ABS. For example, the coil C may enclose the return yoke 200 in a plane spiral shape.

The return yoke tip 220 is prepared at one end of the return yoke 200. The return yoke tip 200 includes side shields 223, which are disposed on both sides of the main pole 140, and a top shield 226, which is laid over across a top region of the main pole 130 and top regions of the side shields 223. Each of the side shields 223 is spaced a first gap g₁ apart from a lateral surface of the main pole 130. The top shield 226 is spaced a second gap g₂ apart from the main pole 140 and also spaced a predetermined distance apart from the side shields 226. Although FIG. 2B illustrates that a distance between the top shield 226 and the main pole 140 is equal to a distance between the top shield 226 and the side shields 223, the present invention is not limited thereto and the distance between the top shield 226 and the main pole 140 may differ from the distance between the top shield 226 and the side shields 223. The side shields 223 and the top shield 226 may be formed of, for example, NiFe. The side shields 223 and the top shield 226 are prepared to improve a field gradient at a track edge, and the first and second gaps g₁ and g₂ may be appropriately controlled. The second gap g₂, which corresponds to a distance between the main pole 140 and the top shield 226, functions as a write gap, and portions of the top and side shields 226 and 223, which are disposed opposite the second gap g₂, are called a throat. A throat height THₛ of the side shield 223 may be equal to or greater than a throat height THₜ of the top shield 226. The throat height THₜ of the top shield 226 directly affects the intensity of a recording magnetic field as compared with the throat height THₛ of the side shield 223. Typically, as the throat height THₜ of the top shield 226 increases, the magnetic field of the main pole 140 that does not pass through the recording medium but travels directly to the top shield 226 and the return yoke 200 increases, thus reducing recording efficiency. Furthermore, when the throat height THₜ of the top shield 226 is excessively small, the characteristics of a recording magnetic field can be degraded due to partial saturation. Therefore, the throat height THₜ of the top shield 226 needs to be appropriately controlled. In the current embodiment of the present invention, the top shield 226 and the side shield 223 are fabricated using separate processes to have the throat heights THₜ and THₛ, respectively. In particular, since the top shield 226, of which throat height THₜ is a more sensitive design variable, has relatively low topography, the fabrication process of the top shield 226 is structurally simple.

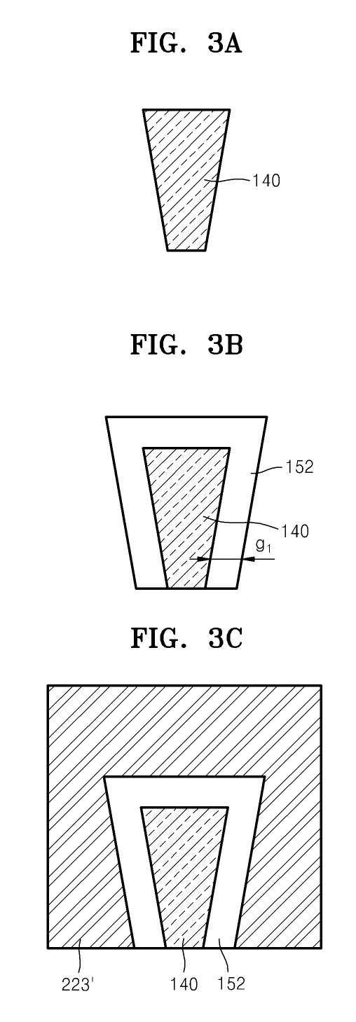

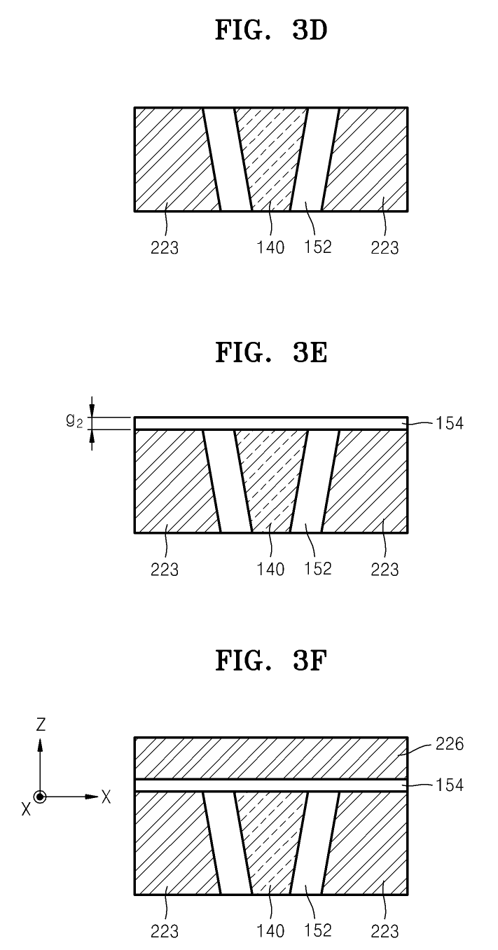

FIGS. 3A through 3F are diagrams for explaining a method of manufacturing a PMR head according to an embodiment of the present invention. Each of the FIGS. 3A through 3F illustrates a portion A of FIG. 2A, which is seen from the ABS (i.e., a YZ plane).

Referring to FIG. 3A, a main pole 140 having a predetermined shape is formed. The main pole 140 is formed on a predetermined substrate (not shown) using a thin film process. Generally, a read head, a portion of a coil, and an insulating layer may be formed on the substrate in advance. For example, the formation of the main pole 140 may include depositing a seed layer, forming a pattern using a lithography process, electroplating the pattern a magnetic material, for example, CoFe or CoNiFe, and shaping an end tip of the main pole 140 using a trimming process.

Referring to FIG. 3B, a first insulating layer 152 is formed to cover top and lateral surfaces of the main pole 140 to a predetermined thickness g₁. The first insulating layer 152 may be formed by depositing, for example, Al₂O₃ using atomic layer deposition (ALD). Since the ALD has excellent step coverage characteristics, the top and lateral surfaces of the main pole 140 can be covered with the first insulating layer 152 to the full. Also, the first insulating layer 152 can be deposited at an atomic scale, so that controlling the thickness of the first insulating layer 152 is easy.

Referring to FIG. 3C, a magnetic layer 223′ to form the side shields is formed enclosing top and lateral surfaces of the first insulating layer 152. The magnetic layer 223′ may be formed by electroplating with a magnetic material, such as NiFe. Thereafter, a portion of the magnetic layer 223′ and the first insulating layer 152 which is formed on the main pole 140 is polished using chemical mechanical polishing (CMP), so that the side shields 223 at both sides of the main pole 140 as shown in FIG. 3D are obtained.

Referring to FIG. 3E, a second insulating layer 154 is formed on the side shields 223, the first insulating layer 152, and the main pole 140. The second insulating layer 154 is formed by depositing a nonmagnetic material, such as Al₂O₃. The second insulating layer 154 functions as a write gap and is formed to a thickness g₂.

Referring to FIG. 3F, a top shield 226 is formed on the second insulating layer 154. The top shield 226 may be formed by electroplating the resultant structure with a magnetic material, such as NiFe. Specifically, the formation of the top shield 226 includes depositing a seed layer, patterning the seed layer using a photolithography process, and electroplating the patterned seed layer with a magnetic material. In this case, a length of the top shield 226 in an x-direction is a throat height (THₜ in FIG. 2B), which sensitively affects recording efficiency. Since the top shield 226 has a lower topography than the side shield 223, the throat height may be controlled to have a lower error tolerance. In the above-described process, the PMR head includes the main pole 140, which is enclosed with a plurality of shields 223 and 226 that are separated from one another.

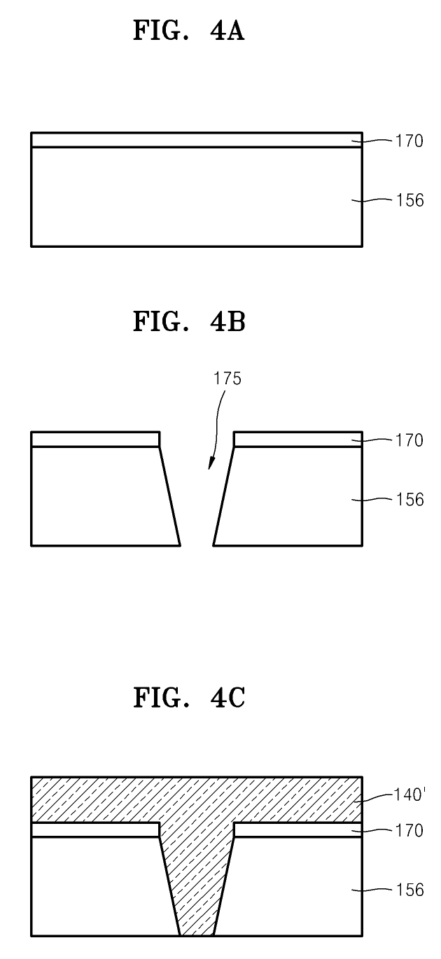

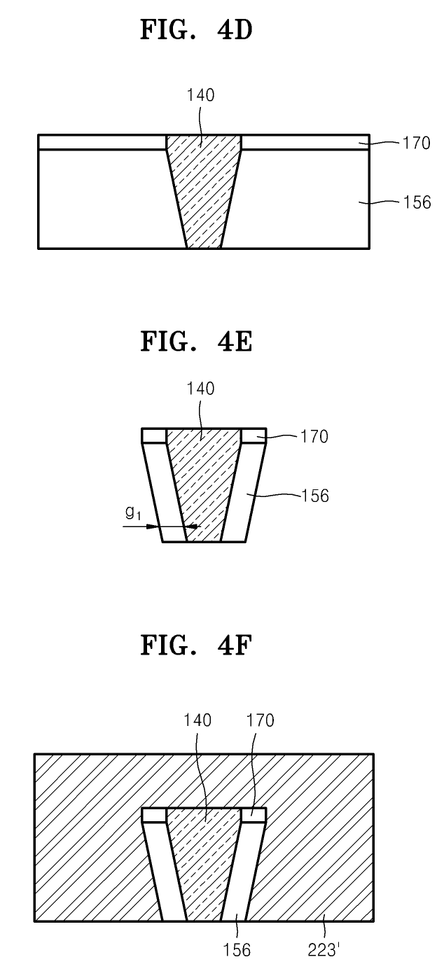

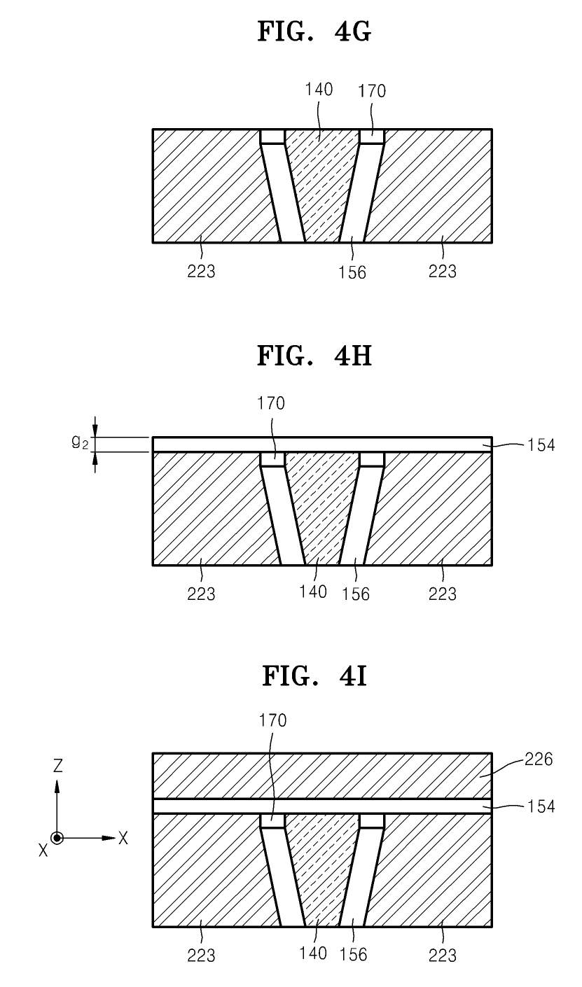

FIGS. 4A through 4F are diagrams for explaining a method of manufacturing a PMR head according to another embodiment of the present invention. The current embodiment differs from the previous embodiment in that a damascene process is employed.

Referring to FIG. 4A, a dielectric layer 156 for a damascene process and a stop layer 170 are sequentially formed. Like in the previous embodiment, subsequent processes will be performed on a substrate (not shown) on which a read head, a portion of a coil, and an insulating layer are formed in advance. The dielectric layer 156 is formed by depositing, for example, a SiN layer or a SiO₂ layer. The dielectric layer 156 may be formed of Al₂O₃. However, when the dielectric layer 156 is formed of SiN or SiO₂, the dielectric layer 156 can be easily etched in a subsequent process without using a toxic Cl-based gas. The stop layer 170, which is to be an etch hard mask layer or a CMP stop layer, is formed by depositing, for example, Ta or Ru.

Referring to FIG. 4B, a trench 175 having a predetermined shape is formed. The trench 175 is formed by etching the stop layer 170 and the dielectric layer 156 in a desired shape of a main pole using, for example, ion beam etching (IBE) or reactive ion etching (RIE). The etching of the stop layer 170 and the dielectric layer 156 may be performed using an Ar ion beam and F-based gas, respectively.

Referring to FIG. 4C, a first magnetic layer 140′ is formed in the trench 175 and on the stop layer 170. The formation of the first magnetic layer 140′ includes depositing a seed layer, patterning the seed layer, and electroplating the patterned seed layer with CoNife or CoFe.

Referring to FIG. 4D, the first magnetic layer 140′ is polished to shape a main pole 140. Thereafter, the stop layer 170 and the dielectric layer 156 disposed on both sides of the main pole 140 are partially etched as shown in FIG. 4E. The remaining dielectric layer 156 is patterned and etched using RIE to a thickness g₁.

Referring to FIG. 4F, a second magnetic layer 223′ is formed. The second magnetic layer 223′ is patterned in a desired shape of a side shield and electroplated with, for example, NiFe. Thereafter, the second magnetic layer 223′ is polished to form side shields 223 as shown in FIG. 4G.

Referring to FIG. 4H, a second insulating layer 154 is formed. The second insulating layer 154 is formed by depositing a nonmagnetic material, for example, Al₂O₃. The second insulating layer 154 functions as a write gap and is formed to a thickness g₂.

Referring to FIG. 4I, a top shield 226 is formed on the second insulating layer 154. The top shield 226 may be formed by electroplating the resultant structure with a magnetic material, such as NiFe. Specifically, the formation of the top shield 226 includes depositing a seed layer, providing plating frame using a photolithography process, and electroplating on the seed layer with the magnetic material. In this case, an x-directional length of the top shield 226 is a throat height (THₜ in FIG. 2B), which sensitively affects recording efficiency. Since the top shield 226 has lower topography than the side shield 223, the throat height may be controlled to have a lower error tolerance. In the above-described process, the PMR head includes the main pole 140, which is enclosed with a plurality of shields 223 and 226 that are separated from one another.

The above-described methods according to the embodiments of the present invention are characterized by forming the top shield 226 and the side shields 223 apart from one another. Thus, the remaining process operations are exemplarily described and may be changed by one of ordinary skill, if required. For instance, although it is described that a distance between the side shield 223 and the top shield 226 is equal to a distance g₂ between the main pole 140 and the top shield 226, the distance between the side shield 223 and the top shield 226 may differ from the distance g₂ between the main pole 140 and the top shield 226. This is because the distance g₂ between the main pole 140 and the top shield 226 is appropriately controlled to function as a write gap, and the distance between the side shield 223 and the top shield 226 may be controlled to have about the same field gradient at a track edge as in a structure in which a side shield and a top shield are connected to each other.

As described above, a PMR head according to the present invention is structured such that a main pole is enclosed by a top shield and side shields of a return yoke tip, which are separated from one another. In this structure, a field gradient at a track edge can be improved to reduce a track pitch and increase the recording density of the PMR head. Furthermore, since the top shield of which throat height is a more sensitive design variable has relatively low topography, controlling the throat height of the top shield to have a lower error tolerance is easy, thus facilitating mass production.

While the present invention has been particularly shown and described with reference to exemplary embodiments thereof, it will be understood by one of ordinary skill in the art that various changes in form and details may be made therein without departing from the spirit and scope of the present invention as defined by the following claims.

What is claimed is:

1. A perpendicular magnetic recording (PMR) head comprising a main pole, a return yoke, and a coil to which current is supplied so that the main pole generates a magnetic field required for recording data in a recording medium, the PMR head comprising:
side shields disposed on both sides of the main pole, each side shield being spaced a first gap apart from the main pole; and
a top shield disposed over and across a top region of the main pole and top regions of the side shields, the top shield spaced a second gap apart from the main pole and spaced a predetermined distance part from the side shield.

2. The PMR head of claim 1, wherein the distance between the top shield and the side shield is equal to the second gap.

3. The PMR head of claim 1, wherein a throat height of the side shield is equal to or greater than a throat height of the top shield.

4. The PMR head of claim 1, further comprising a sub-yoke spaced away from an end tip of the main pole to aid the magnetic field to focus on the end tip of the main pole.

5. The PMR head of claim 4, wherein the sub-yoke is formed on a top surface or a bottom surface of the main pole.

6. The PMR head of claim 1, wherein the main pole is formed of one selected from CoFe and CoNiFe.

7. The PMR head of claim 1, wherein the top shield and the side shields are formed of NiFe.

8. The PMR head of claim 1, wherein the coil is wound around the main pole in a solenoid shape.

9. The PMR head of claim 1, wherein the coil is wound around the return yoke in a plane spiral shape.

10. A method of manufacturing a perpendicular magnetic recording (PMR) head, the method comprising:
forming a main pole and forming side shields on both sides of the main pole to be spaced a first gap apart from the main pole; and
forming a top shield over and across a top region of the main pole and top regions of the side shields to be spaced a second gap apart from the main pole and be spaced a predetermined distance apart from the side shield.

11. The method of claim 10, wherein the forming of the main pole and the side shields comprises:
forming the main pole;
forming a first insulating layer to enclose top and lateral surfaces of the main pole to a thickness almost equal to the first gap;
forming a magnetic layer to form the side shields, wherein the magnetic layer encloses top and lateral surfaces of the first insulating layer; and
polishing a portion of the magnetic layer and the first insulating layer which is formed on the main pole.

12. The method of claim 11, wherein the forming of the first insulating layer comprises depositing an Al₂O₃ layer on the top and lateral surfaces of the main pole using an atomic layer deposition (ALD) technique.

13. The method of claim 10, wherein the forming of the main pole and the side shields comprises:
sequentially forming a first insulating layer and a stop layer;
forming a trench having the same shape as the main pole by etching the first insulating layer and the stop layer;
forming a magnetic layer in the trench and on the stop layer;
polishing the magnetic layer;
etching both lateral portions of the first insulating layer; and
forming the side shields on both sides of the first insulating layer.

14. The method of claim 13, wherein the first insulating layer is formed by depositing one selected from SiN and SiO₂.

15. The method of claim 13, wherein the stop layer is formed by depositing one selected from Ta and Ru.

16. The method of claim 10, wherein the forming of the top shield comprises:
forming a second insulating layer on the side shields and the main pole to a thickness almost equal to the second gap; and
forming the top shield on the second insulating layer.

17. The method of claim 10, wherein the side shield is formed to have a throat height equal to or greater than a throat height of the top shield.

18. The method of claim 10, wherein the main pole is formed of one selected from CoFe and CoNiFe.

19. The method of claim 10, wherein the top shield and the side shields are formed of NiFe.
